(19) United States
(12) Patent Application Publication
(10) Pub. No.: US 2026/0169068 A1
(43) Pub. Date: Jun. 18, 2026

(54) TESTING METHOD FOR ELECTRONIC DEVICE AND TEST SYSTEM

(71) Applicant: Samsung Electronics Co., Ltd., Suwon-si (KR)

(72) Inventors: Jeongyong Park, Suwon-si (KR); Jeeyong Lee, Suwon-si (KR); Do-Han Kim, Suwon-si (KR); Young-Hoon Son, Suwon-si (KR); Insu Choi, Suwon-si (KR); Kideok Han, Suwon-si (KR)

(21) Appl. No.: 19/324,363

(22) Filed: Sep. 10, 2025

(30) Foreign Application Priority Data
Dec. 17, 2024 (KR) 10-2024-0189080

(51) Int. Cl. G01R 31/3183

(52) U.S. Cl. CPC G01R 31/318371; G01R 31/318314

(57) ABSTRACT

A testing method for an electronic device includes receiving a plurality of first test data and a plurality of second test data, generating a plurality of first and second local scores, generating a global score for a common test case for the plurality of first test cases and the plurality of second test cases, replacing at least some of the plurality of first local scores with the global score to generate a plurality of first test scores, replacing at least some of the plurality of second local scores with the global score to generate a plurality of second test scores, and performing a first mutation operation based on a first optimal test case corresponding to the highest score among the plurality of first test scores to generate a first pre-test group.

### CROSS-REFERENCE TO RELATED APPLICATION

This application claims priority to and the benefit of Korean Patent Application No. 10-2024-0189080 filed with the Korean Intellectual Property Office on Dec. 17, 2024, the entire contents of which are incorporated herein by reference.

### BACKGROUND

In manufacturing electronic devices, including semiconductor devices, tests must be conducted to determine optimal operating conditions. Considering limitations on the number of test iterations and various operating conditions, so testing must be conducted by relying on the know-how of engineers. Although desirable operating conditions by know-how exist, a genetic algorithm has been proposed to search for optimal operating conditions more accurately and quickly.

### SUMMARY

The genetic algorithm is a technique for solving optimization problems as a model based on the evolutionary process of the natural world. However, even if the operating conditions of an electronic device suitable for a specific DUT (Device Under Test) are searched for using a genetic algorithm, an overfitting problem may occur where the searched operating conditions are not suitable for other DUTs.

In order to solve the overfitting problem, operating conditions are searched for across multiple DUTs based on a genetic algorithm. However, since the operating conditions that perform well in a specific DUT do not take into account their performance in other DUTs during the search process, it is difficult to find robust operating conditions suitable for multiple DUT environments.

Some aspects of the present disclosure provide test methods for electronic devices, and test systems, that rapidly explore robust operating conditions for electronic devices in multiple DUT environments.

According to some implementations, a test method of an electronic device including receiving a plurality of first test data for a plurality of first test cases and a plurality of second test data for a plurality of second test cases, generating a plurality of first local scores based on the plurality of first test data, generating a plurality of second local scores based on the plurality of second test data, generating a global score for a common test case for the plurality of first test cases and the plurality of second test cases, replacing at least some of the plurality of first local scores with the global score to generate a plurality of first test scores, replacing at least some of the plurality of second local scores with the global score to generate a plurality of second test scores, and performing a first mutation operation based on a first optimal test case corresponding to the highest score among the plurality of first test scores to generate a first pre-test group may be provided.

According to some implementations, a test method of an electronic device including receiving a plurality of first test data for a plurality of first test cases and a plurality of second test data for a plurality of second test cases, generating a plurality of first local scores based on the plurality of first test data, generating a plurality of second local scores based on the plurality of second test data, performing a first mutation operation based on at least some of the plurality of first test cases to generate a first pre-test group, performing a second mutation operation based on at least some of the plurality of first test cases to generate a second pre-test group, and@@@adding a first local optimal case corresponding to the highest score among the plurality of first local scores and a second local optimal case corresponding to the highest score among the plurality of second local scores to the first pre-test groups to generate a plurality of third test cases may be provided.

According to some implementations, a test system including a first electronic device comprising a first memory module configured to output a plurality of first data based on a plurality of first test cases, and configured to generate a plurality of first test data for the plurality of first data, a second electronic device comprising a second memory module configured to output a plurality of first data based on a plurality of first test cases, and configured to generate a plurality of first test data for the plurality of second data, and a test device configured to generate a plurality of first local scores based on the plurality of first test data, generate a plurality of second local scores based on the plurality of second test data, generate a global score for a common test case for the plurality of first test cases and the plurality of second test cases, replace at least some of the plurality of first local scores with the global score to generate a plurality of first test scores, replace at least some of the plurality of second local scores with the global score to generate a plurality of second test scores, and perform a first mutation operation based on a first optimal test case corresponding to the highest score among the plurality of first test scores to generate a first pre-test group may be provided.

### BRIEF DESCRIPTION OF THE DRAWINGS

FIG. 1 is a block diagram illustrating an example of a test system.

FIG. 2 is a block diagram illustrating an example of a test device.

FIG. 3 illustrates an example of a genetic algorithm tool.

FIGS. 4 to 6 illustrate examples of test cases and test data.

FIG. 7 is a flowchart illustrating an example of a testing method for an electronic device.

FIGS. 8 to 12 are diagrams illustrating aspects of an example of a testing method for an electronic device.

FIG. 13 is a block diagram illustrating an example of a test system.

FIG. 14 is a block diagram illustrating an example of a test system.

FIG. 15 is a block diagram illustrating an example of a test device.

### DETAILED DESCRIPTION

As those skilled in the art will realize, the described examples may be modified in various different ways, all without departing from the spirit or scope of the present disclosure.

In order to clearly explain the present disclosure, parts irrelevant to the description are omitted, and identical or similar reference numerals are assigned to identical or similar components throughout the specification.

In addition, unless explicitly stated to the contrary, the word “comprise,” and variations such as “comprises” and “comprising,” should be understood to imply the inclusion of stated elements but not the exclusion of any other elements.

It should be further understood by those skilled in the art that if a specific number of an introduced claim recitation is intended, such an intent will be explicitly recited in the claim, and in the absence of such recitation no such intent is present. For example, to facilitate understanding, the following appended claims may contain usage of the introductory phrases “at least one” and “one or more” to introduce claim recitations. However, the use of such phrases should not be understood as a limitation described by the unambiguous article “one,” as one example.

Furthermore, in those instances where a convention analogous to “at least one of A, B, and C, etc.” is used, in general such a construction is intended in the sense in which one having skill in the art would understand the convention (e.g., “a system having at least one of A, B, and C” would include but not be limited to systems that have A alone, B alone, C alone, A and B together, A and C together, B and C together, and/or A, B, and C together, etc.)

Alternatively, a disjunctive word and/or phrase presenting two or more alternative terms, whether in the description, claims, or drawings, should be understood as likely to include one of the terms, either of the terms, or both of the terms unless context dictates otherwise. For example, the phrase “A or B” should be typically understood to include the possibilities of “A” or “B” or “A and B.”

In this specification, “a module,” “a unit,” or “a part” can be configured to perform at least one function or operation, and may be realized as hardware, such as a processor or integrated circuit, software that is executed by a processor, or a combination thereof.

As discussed above, when searching for operating conditions using the Genetic Algorithm for multiple DUTs, the search directions for each DUT may not be considered collectively, making it difficult to find operating conditions suitable for all DUTs.

Some implementations of the present disclosure improve the technology of device testing by, for example, including processes of: i) locally scoring the test performance of multiple test cases (combinations of operating conditions) for each DUT of multiple DUT, ii) generating a global score for common test cases shared among the multiple DUTs based on multiple local scores, replacing the local scores of the common test cases with the global score, iii) selecting the optimal test cases for each DUT based on the scores, and performing mutation operations based on the selected optimal test cases to generate subsequent generations for each DUT; and iv) adding locally optimized test cases for each DUT to the generated subsequent generations.

Through one or more of steps i) to iv), performance can be quantified to explore test cases suitable for multiple DUTs, thereby incorporating DUT-specific optimal test cases into subsequent generations to enable cross-verification of test cases across different DUTs and prevent exploration in incorrect directions. This can result in improved performance of the DUTs by allowing the DUTs to be configured with operating conditions that are more robust across device-to-device variation and other variable factors.

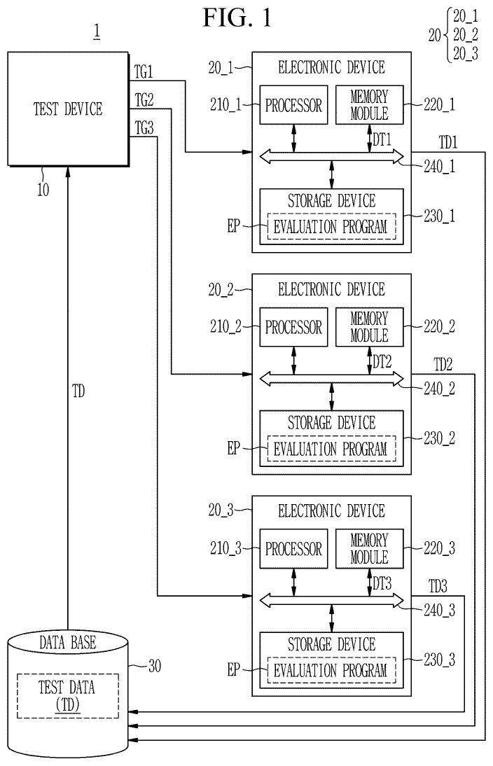

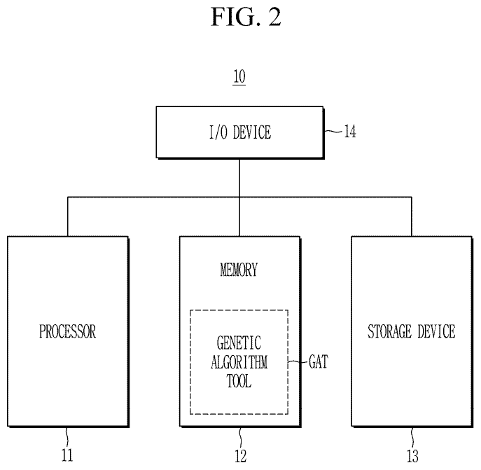

FIG. 1 is a block diagram illustrating an example of a test system. FIG. 2 is a block diagram illustrating an example of a test device.

Referring to FIGS. 1 and 2, a test system 1 may include a test device 10, a plurality of electronic devices 20, and a database 30. The plurality of electronic devices 20 may include first to third electronic devices 20_1 to 20_3.

The test system 1 may repeatedly generate subsequent generations for multiple test groups TG1, TG2, TG3 based on a genetic algorithm to efficiently search for optimal test cases robust across multiple electronic devices 20_1 to 20_3. In the test system 1, a plurality of electronic devices 20_1 to 20_3 may receive corresponding test groups TG1, TG2, TG3, respectively, and perform measurement operations for each test case included in the received test groups TG1, TG2, TG3 to generate test data TD1, TD2, TD3 which are raw data. The test device 10 may perform individual optimization for each test group TG1, TG2, TG3 by considering test data acquired from other electronic devices and generate individual subsequent generations for each test group TG1, TG2, TG3.

In the present disclosure, a ‘test group’ may be defined as a set of ‘test cases’ applied to a specific electronic device among a plurality of electronic devices 20_1 to 20_3 within a test system 1, and a ‘test case’ may be defined as a combination of operating conditions for a component within an electronic device. For example, a ‘test case’ may be a combination of operating conditions for a memory module, which is a component of an electronic device, and the ‘test case’ may be expressed as a string or bit string and include at least a part of the MRS (Mode Register Set) information for testing of the memory module.

The test device 10 may include a processor 11, memory 12, a storage device 13, and an input/output device 14. The processor 11 may include computational circuitry.

The test device 10 may be a computer-based test device. The test device 10 may use a genetic algorithm as part of the test system 1. The test device 10 may generate subsequent generations of test groups TG1, TG2, TG3 corresponding to each of the plurality of electronic devices 20_1 to 20_3 using a genetic algorithm based on test data TD1, TD2, TD3 measured from the plurality of electronic devices 20_1 to 20_3 The test device 10 can search for optimal test cases that are robust across multiple electronic devices 20_1 to 20_3 through the generation of subsequent generations. In the operation of generating a subsequent generation, the test device 10 may quantify separately generated test data TD1, TD2, TD3 in a unified manner, generate a subsequent generation by reflecting (or based on) a portion of the test data measured in another electronic device, and add a local optimal test case that is optimal in each electronic device to the subsequent generation.

According to some implementations, the test device 10 may be a dedicated device for exploring test cases for multiple electronic devices 20, but may also be a computer for running various application programs. The test device 10 may be a stationary computing system such as a desktop computer, workstation, server, etc., or a portable computing system such as a laptop computer, smartphone, and the like.

A processor 11, a memory 12, a storage device 13, and an input/output device 14 may be connected to each other through a bus, and the processor 11 may control the memory 12, the storage device 13, and the input/output device 14.

The processor 11 may execute a genetic algorithm tool GAT. According to some implementations, the processor 11 may execute a genetic algorithm tool GAT to perform various processing operations related to a genetic algorithm operation.

The processor 11 may be at least one of various types of processors such as a CPU (Central Processing Unit), a GPU (Graphics Processing Unit), an NPU (Neural Processing Unit), a DPU (Data Processing Unit), or a combination thereof. According to some implementations, the processor 11 may include a single core processor or a multi-core processor.

The processor 11 may control to provide the first to third test groups TG1 to TG3 to the corresponding first to third electronic devices 20_1 to 20_3, respectively. For example, the processor 11 may control the test device 10 to provide a first test group TG1 to a first electronic device 20_1, a second test group TG2 to a second electronic device 20_2, and a third test group TG3 to a third electronic device 20_3.

The processor 11 may receive test data TD from a database 30. According to some implementations, the processor 11 may asynchronously receive each of the first to third test data TD1 to TD3 measured from each of the first to third electronic devices 20_1 to 20_3.

The processor 11 may perform a scoring operation on test data TD in a unified manner to generate a local score for a test case. A local score may be a performance indicator generated based on test data measured on a particular electronic device. The processor 11 may perform a scoring operation on the first test data TD1 for the test cases in the first test group TG1, the second test data TD2 for the test cases in the second test group TG2, and the third test data TD3 for the test cases in the third test group TG3 in a unified manner, thereby generating a local score as a performance indicator for the entirety of the test cases.

The processor 11 may find a local optimal test case having the highest local score among test cases for each of a plurality of test groups TG1 to TG3. For example, the processor 11 may find a first local optimal test case having the highest local score among the test cases in the first test group TG1. Similarly, the processor 11 may find a second local optimal test case having the highest local score among the test cases in the second test group TG2, and may find a third local optimal test case having the highest local score among the test cases in the third test group TG3.

The processor 11 may generate a global score based on a local score for common test cases common to multiple test groups TG1 to TG3. The global score may be a performance indicator that comprehensively reflects the first to third test data TD1 to TD3 measured on the first to third electronic devices 20_1 to 20_3.

For example, the processor 11 may perform one or more operations to generate a global score based on a local score generated by applying a common test case to a first electronic device 20_1, a local score generated by applying a common test case to a second electronic device 20_2, and a local score generated by applying a common test case to a third electronic device 20_3. The operations may include arithmetic mean, geometric mean, minimum selection, weighted mean, etc., but are not limited to these.

The processor 11 may select the test case with the highest global score among the common test cases.

The processor 11 may generate multiple test scores for each of multiple test groups TG1 to TG3 by replacing local scores with global scores for common test cases. A test score may be a performance indicator that reflects a local score obtained from a specific electronic device plus a global score obtained from multiple electronic devices 20_1 to 20_3.

The processor 11 may generate an optimal test case having the highest test score among test cases for each of the plurality of test groups TG1 to TG3. For example, the processor 11 may find a first optimal test case having the highest test score among the test cases in the first test group TG1. Similarly, the processor 11 may find a second optimal test case having the highest test score among the test cases in the second test group TG2, and may find a third optimal test case having the highest test score among the test cases in the third test group TG3.

The processor 11 may perform mutation operations for each optimal test case for multiple test groups TG1 to TG3 to generate pre-test groups for each of the multiple test groups TG1 to TG3. For example, the processor 11 may perform a mutation operation based on a first optimal test case for the first test group TG1 to generate a first pre-test group for the first test group TG1. Similarly, the processor 11 may perform a mutation operation based on a second optimal test case for the second test group TG2 to generate a second pre-test group for the second test group TG2, and perform a mutation operation based on a third optimal test case for the third test group TG3 to generate a third preliminary test group for the third test group TG3.

The processor 11 may add local optimal test cases for the plurality of test groups TG1 to TG3 to multiple preliminary test groups for each of test groups TG1 to TG3 to generate a plurality of subsequent test groups. For example, the processor 11 may add local optimal test cases for each of the test groups TG1 to TG3 to a first pre-test group for the first test group TG1 to generate a first subsequent test group for the first test group TG1. Similarly, the processor 11 may add the local optimal test cases for the plurality of test groups TG1 to TG3 to a second pre-test group for the second test group TG2, and may add the local optimal test cases for the plurality of test groups TG1 to TG3 to a third pre-test group for the third test group TG3.

The processor 11 may provide the generated subsequent test groups to the corresponding first to third electronic devices 20_1 to 20_3. For example, the processor 11 may provide a first subsequent test group for the first test group TG1 to the first electronic device 20_1. Similarly, the processor 11 may provide a second subsequent test group for the second test group TG2 to the second electronic device 20_2, and provide a third subsequent test group for the third test group TG3 to the third electronic device 20_3.

Memory 12 may be used as the main memory or system memory of the test device 10. The genetic algorithm tool GAT running on a processor 11 may be loaded into memory 12. Memory 12 may store various types of information used in the genetic algorithm operation and store the results of intermediate operations of the genetic algorithm.

The processor 11 may execute the genetic algorithm tool GAT loaded into the memory 12 to perform the various operations described herein.

According to some implementations, memory 12 may include volatile memory devices such as DRAM, SDRAM (synchronous DRAM), DDR SDRAM (double data rate SDRAM), LPDDR SDRAM (low power double data rate SDRAM), GDDR SDRAM (graphics double data rate SDRAM), DDR2 SDRAM, DDR3 SDRAM, DDR4 SDRAM, DDR5 SDRAM, etc. According to some implementations, the memory 12 may include not only DRAM devices but also, or instead, non-volatile memory such as PRAM, SRAM, MRAM, RRAM, FRAM, Hybrid RAM, or NAND flash.

The storage device 13 may store program codes (e.g., computer-readable program codes) for executing the genetic algorithm tool GAT.

The storage device 13 may include a non-volatile memory device and a non-volatile memory controller for the non-volatile memory device. For example, the non-volatile memory device may include a hard drive, optical memory, NAND flash memory, and the like. According to some implementations, the storage device 13 may include non-volatile memory, volatile memory, or a combination or portion thereof, any of which may be referred to as a “storage medium.”

In some implementations, the non-volatile memory device may be configured to store data in a semi-permanent or substantially permanent form.

The input/output device 14 may include input devices such as a keyboard, an operating panel, or various data reading devices, and output devices such as a monitor, a printer, and a recording device, for example.

The plurality of electronic devices 20 may include first to third electronic devices 20_1 to 20_3, or any other number of electronic devices. According to some implementations, each of the first to third electronic devices 20_1 to 20_3 may be, or correspond to, a separate DUT (Device Under Test) or an environment of the DUT. In each of the first to third electronic devices 20_1 to 20_3, test cases of each of the first to third test groups TG1, TG2, TG3 can be applied. For example, a test case within a first test group TG1 may include MRS information for testing of a memory device and may be applied to a first memory module (220_1) of a first electronic device (20_1).

Each of the first to third electronic devices (20_1 to 20_3) may be a computer-based test device. When a test case is applied to each of the first to third electronic devices 20_1 to 20_3, each of the first to third electronic devices 20_1 to 20_3 may perform a measurement operation based on the test case and output first to third test data TD1 to TD3 corresponding to the test case.

The first electronic device 20_1 may include a first processor 210_1, a first memory module 220_1, a first storage device 230_1, and a first system bus 240_1.

The first processor 210_1, the first memory module 220_1, and the first storage device 230_1 may be connected to each other through the first system bus 240_1, and the first processor 210_1 may control the first memory module 220_1 and the first storage device 230_1. According to some implementations, the first system bus 240_1 may be physically implemented through a PCB substrate disposed in the first electronic device 20_1.

The first processor 210_1 may execute a measurement program (or evaluation program) EP. According to some implementations, the first processor 210_1 may execute the measurement program EP to apply a test case of the first test group TG1, perform a measurement operation according to the application of the test case, and perform various processing operations related to the measurement operation. For example, the first processor 210_1 may execute the measurement program EP to apply a test case of the first test group TG1 to the first memory module 220_1 and control the input/output operation of the first data signal DT1 input/output from the first memory module 220_1. The first processor 210_1 may execute the measurement program EP to measure a signal margin for the first data signal DT1. The above signal margin may include voltage margin, timing margin, etc.

The first processor 210_1 may be at least one of processors such as a central processing unit (CPU), a graphics processing unit (GPU), a neural processing unit (NPU), a data processing unit (DPU), or a combination thereof. According to some implementations, the first processor 210_1 may include a single core processor or a multi-core processor.

The first memory module 220_1 may be used as the main memory or system memory of the first electronic device 20_1. The measurement program EP running on the first processor 210_1 may be loaded into the first memory module 220_1. The first memory module 220_1 may input and output the first data signal DT1 along with the execution of the measurement program EP. The first processor 210_1 may perform a measurement operation according to the application of a test case within the first test group TG1 by executing the measurement program EP loaded into the first memory module 220_1.

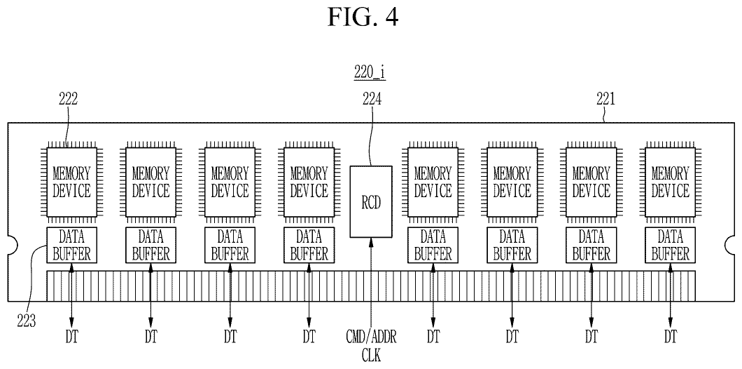

For example, the first processor 210_1 may execute the measurement program EP loaded into the first memory module 220_1, thereby applying a test case within the first test group TG1 to the first memory module 220_1. As the test case within the first test group TG1 is applied, the signal margin of the first data signal DT1 input/output may be measured to generate the first test data TD1. As another example, the first processor 210_1 may execute the measurement program EP loaded into the first memory module 220_1, thereby applying a test case within the first test group TG1 to the first memory module 220_1. As the test case within the first test group TG1 is applied, the bandwidth of the first data signal DT1 input/output may be measured to generate the first test data TD1. A detailed explanation of examples of test cases and test data will be provided later in the descriptions of FIGS. 4 to 6.

The first test data TD1 generated may be transmitted to a database 30 and stored in the database 30.

The first memory module 220_1 may include volatile memory devices such as DRAM, SDRAM (synchronous DRAM), DDR SDRAM (double data rate SDRAM), LPDDR SDRAM (low power double data rate SDRAM), GDDR SDRAM (graphics double data rate SDRAM), DDR2 SDRAM, DDR3 SDRAM, DDR4 SDRAM, DDR5 SDRAM, etc. According to some implementations, the first memory module 220_1 may be implemented in the form of a DIMM (dual in-line memory module).

The first storage device 230_1 may store program codes (e.g., computer-readable program codes) for executing the measurement program EP.

The first storage device 230_1 may include a non-volatile memory device and a non-volatile memory controller for the non-volatile memory device. For example, the non-volatile memory device may include a hard drive, optical memory, NAND flash memory, and the like. In some implementations, the first storage device 230_1 may include non-volatile memory, volatile memory, and combinations or portions thereof, any of which may be referred to as a “storage medium.”

In some implementations, the non-volatile memory device may be configured to store data in a semi-permanent or substantially permanent form.

The second electronic device 20_2 may include a second processor 210_2, a second memory module 220_2, a second storage device 230_2, and a second system bus 240_2. Each of the second processor 210_2, the second memory module 220_2, the second storage device 230_2, and the second system bus 240_2 may correspond to each of the first processor 210_1, the first memory module 220_1, the first storage device 230_1, and the first system bus 240_1, respectively.

For ease of explanation below, the second processor 210_2, the second memory module 220_2, the second storage device 230_2, and the second system bus 240_2 will be described with a focus on differences from the first processor 210_1, the first memory module 220_1, the first storage device 230_1, and the first system bus 240_1.

The second processor 210_2 may execute a measurement program EP. According to some implementations, the second processor 210_2 may execute the measurement program EP to apply a test case in the second test group TG2, perform a measurement operation according to the application of the test case, and perform various processing operations related to the measurement operation. For example, the second processor 210_2 may execute the measurement program EP to control input/output operations of the second data signal DT2 for the second memory module 220_2 and measure a signal margin for the second data signal DT2.

The second memory module 220_2 may input and output a second data signal DT2 along with the execution of the measurement program EP. The second processor 210_2 may perform a measurement operation according to the application of a test case within the second test group TG2 by executing the measurement program EP loaded into the second memory module 220_2.

The third electronic device 20_3 may include a third processor 210_3, a third memory module 220_3, a third storage device 230_3, and a third system bus 240_3. Each of the third processor 210_3, the third memory module 220_3, the third storage device 230_3, and the third system bus 240_3 may correspond to each of the first processor 210_1, the first memory module 220_1, the first storage device 230_1, and the first system bus 240_1, respectively.

For ease of explanation below, the third processor 210_3, the third memory module 220_3, the third storage device 230_3, and the third system bus 240_3 will be described with a focus on differences from the first processor 210_1, the first memory module 220_1, the first storage device 230_1, and the first system bus 240_1.

The third processor 210_3 may execute a measurement program EP. According to some implementations, the third processor 210_3 may execute the measurement program EP to apply a test case of the third test group TG3, perform a measurement operation according to the application of the test case, and perform various processing operations related to the measurement operation. For example, the third processor 210_3 may execute the measurement program EP to control input/output operations of the third data signal DT3 for the third memory module 220_3 and measure a signal margin for the third data signal DT3.

The third memory module 220_3 may input and output a third data signal DT3 along with the execution of the measurement program EP. The third processor 210_3 may perform a measurement operation according to the application of a test case within the third test group TG3 by executing a measurement program EP loaded into the third memory module 220_3.

Each of the first to third electronic devices 20_1 to 20_3 commonly includes a processor, a memory module, a storage device, and a system bus, but the respective components of the first to third electronic devices 20_1 to 20_3 may differ from each other in terms of products or manufacturing processes, etc. Due to this difference, even if the same test case is applied to the first to third electronic devices 20_1 to 20_3, the performances of the first to third electronic devices 20_1 to 20_3 may differ from each other and each of the first to third electronic devices 20_1 to 20_3 may output different test data.

The test device 10 can efficiently search for optimal test cases that are robust across environmental differences in multiple electronic devices 20_1 to 20_3 through a genetic algorithm tool GAT.

In the drawing, the plurality of electronic devices 20_1 to 20_3 are illustrated as including three electronic devices, but the number of electronic devices in the drawing is only an example and does not limit the technical idea of the present disclosure. According to some implementations, the number of test groups may vary as the number of multiple electronic devices in the test system 1 varies.

According to some implementations, as the generation of the test group moves to a subsequent generation, the number of the plurality of electronic devices and the number of the test groups can be adjusted to suit the purpose of the test operation of the test system 1.

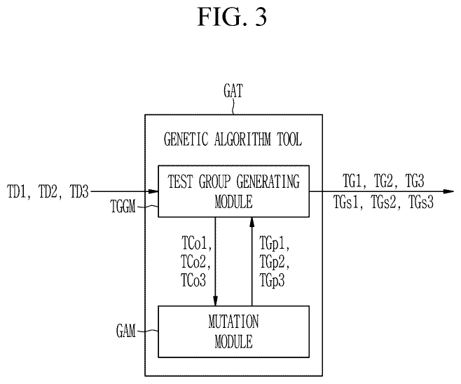

FIG. 3 illustrates an example of a genetic algorithm tool.

Referring to FIGS. 1 to 3, the genetic algorithm tool GAT may include a test group generating module TGGM and a mutation module GAM. The test group generating module TGGM may generate the first to third test groups TG1 to TG3.

The test group generating module TGGM may receive the first to third test data TD1 to TD3 corresponding to first to third test groups TG1 to TG3. The test group generating module TGGM may generate first to third optimal test cases TCo1, TCo2, TCo3 for each of the first to third test groups TG1 to TG3 by considering (or based on) the first to third test data TD1 to TD3 as a whole. The first to third optimal test cases TCo1, TCo2, TCo3 generated may be provided to the mutation module GAM.

The test group generating module TGGM may generate the first to third subsequent test groups TGs1 to TGs3 based on the first to third pre-test groups TGp1 to TGp3 provided from the mutation module GAM. The first to third subsequent test groups TGs1 to TGs3 may be subsequent generations of the first to third test groups TG1 to TG3. The first to third subsequent test groups TGs1 to TGs3 generated may be provided to multiple electronic devices 20_1 to 20_3 as new test groups.

The mutation module GAM may receive the first to third optimal test cases TCo1, TCo2, TCo3 and perform mutation operations for the first to third optimal test cases TCo1, TCo2, TCo3, respectively, to generate the first to third pre-test groups TGp1 to TGp3, respectively. For example, the mutation module GAM may generate a first pre-test group TGp1 based on the first optimal test case TCo1.

The mutation module GAM may randomly modify at least some of the operating conditions within the first to third optimal test cases TCo1, TCo2, TCo3 in the mutation operation. The information on operating conditions may be freely modified as long as it does not exceed a predefined range in the mutation operation.

For example, the mutation module GAM may generate the first pre-test group TGp1 by randomly modifying at least some of the operating conditions in the first optimal test case TCo1. Similarly, the mutation module GAM may generate the second pre-test group TGp2 by randomly modifying at least some of the operating conditions within the second optimal test case TCo2. The mutation module GAM may generate the third pre-test group TGp3 by randomly modifying at least some of the operating conditions in the third optimal test case TCo3.

The mutation module GAM may generate a predefined number of test cases from mutation operations. According to some implementations, as the number of test groups in the test system 1 increases, the mutation module GAM may generate a smaller number of test cases in mutation operations. The test system 1 can rapidly transition from generation to generation by reducing the number of measurement operations on a particular electronic device while maintaining the overall number of test iteration for one generation.

FIGS. 4 to 6 illustrate examples of test cases and test data according to some implementations. Specifically, when the first to third memory modules 220_1 to 220_3 of FIG. 1 are implemented as DIMMs, each of the first to third memory modules 220_1 to 220_3 may be expressed as illustrated for the memory module 220_i of FIG. 4.

Referring to FIG. 1 and FIGS. 4 to 6, a memory module 220_i may include memory devices 222, data buffers 223 corresponding to the memory devices 222, and an RCD (Registering Clock Driver) 224.

The memory devices 222, the data buffers 223, and the RCD 224 may be mounted on a printed circuit board 221. the data buffers 223 corresponding to the memory devices 222 may be connected through a signal line inside the printed circuit board 221, and the memory devices 222 and the RCD 224 may be connected through a signal line inside the printed circuit board 221.

The data buffers 223 may buffer data signals DT input/output from the memory module (220_i) and transmit/receive data signals DT to/from the memory devices 222. The RCD 224 may have the function of buffering and re-driving command CMD, address ADDR, clock CLK and control signals received from the memory controller. The command CMD, address ADDR, clock CLK and control signals output from the RCD 224 may be provided to the memory devices 222.

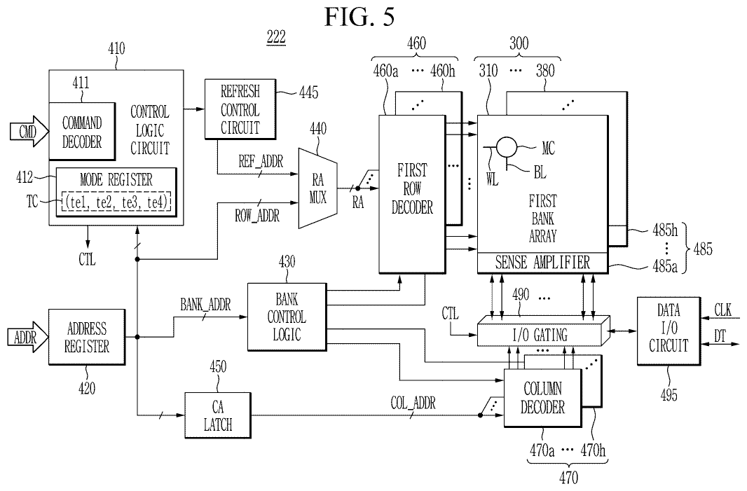

As shown in FIG. 5, the memory devices 222 may include a memory cell array 300, a row decoder 460, a sense amplifier unit 485, a control logic circuit 410, an address register 420, a bank control logic 430, a refresh control circuit 445, a column address latch 450, a row address multiplexer 440, a column decoder 470, an input/output gating circuit 490, and a data input/output buffer 495.

The memory cell array 300 may include a predetermined number of memory banks 310 to 380. In addition, according to some implementations, the sense amplifier unit 485, row decoder 460, and column decoder 470 may include, respectively, a plurality of bank sense amplifiers 485a to 485h, a plurality of bank row decoders 460a to 460h, and a plurality of bank column decoders 470a to 470h connected to each of memory bank 310 to 380, but is not limited to.

The memory cell array 300 may include a plurality of word lines WL, a plurality of bit lines BL, and multiple memory cells MC located at the intersections of the word lines WL and the bit lines BL.

The control logic circuit 410 may control the operation of the memory device 222. For example, the control logic circuit 410 may generate control signals to cause the memory device 222 to perform a write operation or a read operation. The control logic circuit 410 may include a command decoder 411 for decoding a command CMD received from the RCD 224 and a mode register 412 for setting the operation mode and operation conditions of the memory device 222.

For example, the command decoder 411 may decode a light enable signal, a row address strobe signal, a column address strobe signal, a channel select signal, etc. to generate a control signal corresponding to the command CMD.

The mode register 412 may store MRS information. The MRS information may include setting information for setting the operation mode of the memory device 222, test MRS information corresponding to the operation conditions te1 to te4 of the memory device 222 in a test situation, etc. Based on the MRS information stored in the mode register 412, the operation mode and operation conditions of the memory device 222 may be set.

A test case TC may include information on operating conditions te1 to te4 of a memory device 222, which is MRS information for testing, and a mode register 412 may store a test case TC which is a combination of information on operating conditions te1 to te4.

The operating conditions te1 to te4 may be information for operating the memory device 222, and for example, the operating conditions te1 to te4 may include voltage information such as core voltage in the row decoder 460 and the column decoder 470, input/output voltage in the data input/output buffer 495, reference voltage, and time information such as skew correction time in the data input/output buffer 495, etc. In FIG. 5, the number of operating conditions is illustrated as four, but this is an example for ease of explanation, and the technical idea of the present disclosure is not limited to that number of operating conditions.

The memory device 222 may perform a memory operation based on the application of a test case TC and input/output a data signal DT. The measurement program EP may measure the signal margin of the data signal DT and generate test data TD. According to some implementations, the signal margin of the data signal DT may be test data TD that varies depending on the application of the test case TC.

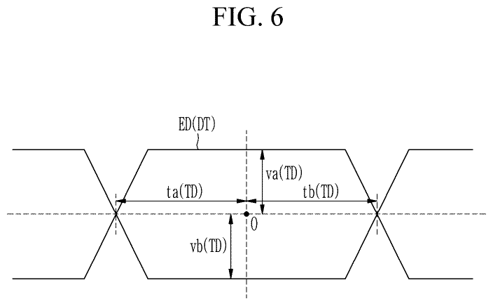

For example, taking FIG. 6 as an example, a data signal DT may be input/output with the performance of signal margins of an a-th timing margin ta, a b-th timing margin tb, an a-th voltage margin va, and a b-th voltage margin vb based on the center O of the eye diagram ED. According to some implementations, the a-th timing margin ta, the b-th timing margin tb, the a-th voltage margin va, and/or the b-th voltage margin vb are performance indicators representing reliability and stability for transmission of a data signal DT, and may be test data TD that varies depending on application of a test case TC.

The address register 420 may receive an address ADDR including a bank address BANK_ADDR, a row address ROW_ADDR, and a column address COL_ADDR from the RCD 224. The address register 420 may provide the bank address BANK_ADDR to the bank control logic 430 and the row address ROW_ADDR to the row address multiplexer 440.

The bank control logic 430 may generate bank control signals in response to a bank address BANK_ADDR. In response to the bank control signals, the row decoder 460 and the column decoder 470 may activate the corresponding bank.

The row address multiplexer 440 may receive a row address ROW_ADDR from the address register 420 and a refresh row address REF_ADDR from the control logic circuit 410. The row address multiplexer 440 may selectively output the row address ROW_ADDR or the refresh row address REF_ADDR as the row address RA. The row address RA output from the row address multiplexer 440 may be provided to the row decoder 460.

The column address latch 450 may receive a column address COL_ADDR from the address register 420 and temporarily store the received column address COL_ADDR. Additionally, the column address latch 450 may incrementally increase the column address COL_ADDR in burst mode. The column address latch 450 may apply a temporarily stored or incrementally increased column address to the column decoder 470.

The column decoder 470 may activate a sense amplifier corresponding to the bank address BANK_ADDR and the column address COL_ADDR through an input/output gating circuit 490, in relation to a bank activated by the bank control logic 430.

The input/output gating circuit 490 may include circuits for gating input/output data, as well as input data mask logic, data registers, and multiplexers.

The data input/output buffer 495 may synchronize the data signal DT input/output from the data buffers 223 to the clock CLK and adjust the voltage value of the data signal DT.

When the first to third memory modules 220_1 to 220_3 of FIG. 1 are implemented as DIMMs like the memory module 220_i, each of the first to third memory modules 220_1 to 220_3 may commonly include a printed circuit board, a data buffer, an RCD, and a memory device. However, each component of the memory modules 220_1 to 220_3 may differ from each other due to the product or manufacturing process. Due to this difference, even if the same test case is applied to the memory devices, the performance of the first to third memory modules 220_1 to 220_3 may differ, and the first to third electronic devices 20_1 to 20_3 of FIG. 1 may generate different test data.

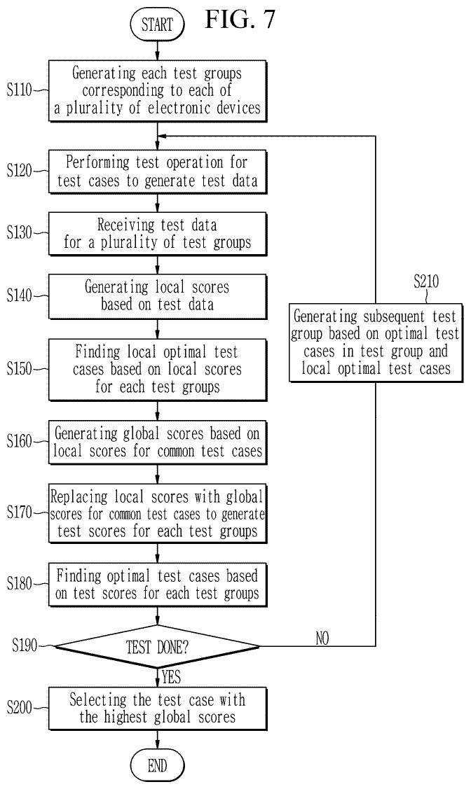

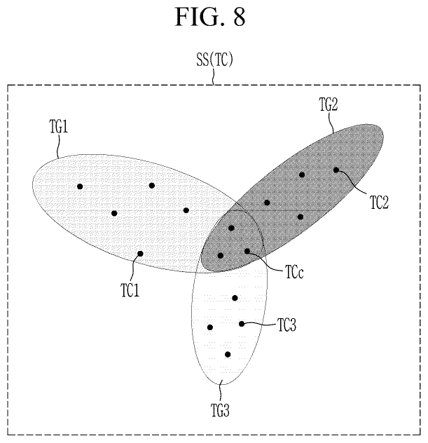

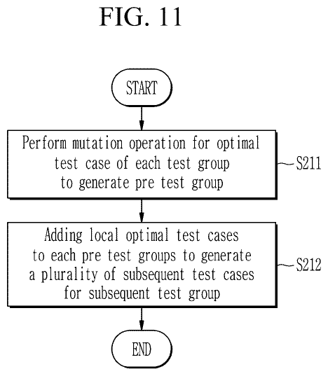

FIG. 7 is a flowchart illustrating an example of a testing method for an electronic device. FIGS. 8 to 12 are drawings for explaining the example of the testing method. FIG. 11 is a flowchart illustrating an example of step S210 of FIG. 7.

Referring to FIGS. 1 to 3 and 7, the test group generating module TGGM generates test groups TG1 to TG3 corresponding to each of a plurality of electronic devices 20_1 to 20_3 (S110).

With additional reference to FIG. 8, the first to third test groups TG1 to TG3 generated may be defined in a search space SS for test cases TC. The first test group TG1 may include a plurality of first test cases TC1, the second test group TG2 may include a plurality of second test cases TC2, and the third test group TG3 may include a plurality of third test cases TC3.

The first to third test groups TG1 to TG3 may include at least one common test case TCc having the same test case, and each of the plurality of first to third test cases TC1 to TC3 may include the at least one common test case TCc.

A plurality of electronic devices 20_1 to 20_3 perform measurement operations based on a plurality of corresponding test cases TC1 to TC3 to generate a plurality of test data TD1 to TD3 (S120).

The test device 10 may provide each of the first to third test groups TG1 to TG3 to each of the corresponding plurality of electronic devices 20_1 to 20_3. The test device 10 may provide a plurality of first test cases TC1 corresponding to a first test group TG1 to a first electronic device 20_1, a plurality of second test cases TC2 corresponding to a second test group TG2 to a second electronic device 20_2, and a plurality of third test cases TC3 corresponding to a third test group TG3 to a third electronic device 20_3.

The first electronic device 20_1 may apply the plurality of first test cases TC1 in a first test group TG1 and perform a measurement operation to generate the plurality of first test data TD1. The second electronic device 20_2 may apply the plurality of second test cases TC2 in the second test group TG2 and perform a measurement operation to generate the plurality of second test data TD2. The third electronic device 20_3 may apply the plurality of third test cases TC3 of a third test group TG3 and perform a measurement operation to generate the plurality of third test data TD3.

The first to third test data TD1 to TD3 generated may be provided to a database 30 and stored in the database 30.

The test device 10 receives the plurality of test data TD1 to TD3 for the plurality of test groups TG1 to TG3 (S130).

The test device 10 may receive the plurality of test data TD1 to TD3 for the plurality of test groups TG1 to TG3 from the database 30.

The test group generating module TGGM generates local scores based on test data TD (S140).

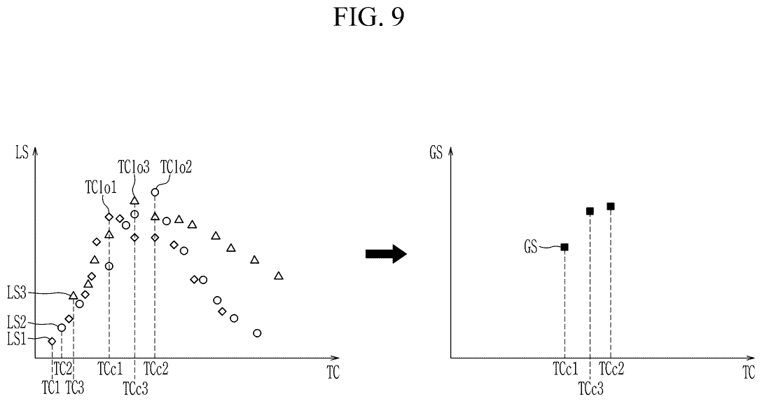

With additional reference to FIG. 9, the test group generating module TGGM may perform a scoring operation on the plurality of first to third test data TD1 to TD3 in a unified manner to generate local scores LS for the test cases TC.

The test group generating module TGGM may generate local scores LS for test cases TC by setting weights for each performance factor of test data TD. Taking FI. 6 as an example, the test group generating module TGGM may set and calculate individual weights for each of the a-th timing margin ta, the b-th timing margin tb, the a-th voltage margin va, and the b-th voltage margin vb, which are test data TD, to generate a local score LS. For example, the local score LS may be generated as a sum or other combined value of the weighted performance factors.

The test group generating module TGGM may generate a plurality of first local scores LS1 for the plurality of first test cases TC1 based on the plurality of first test data TD1 for the plurality of first test cases TC1. The test group generating module TGGM may generate a plurality of second local scores LS2 for the plurality of second test cases TC2 based on the plurality of second test data TD2 for the plurality of second test cases TC2. The test group generating module TGGM may generate a plurality of third local scores LS3 for the plurality of third test cases TC3 based on the plurality of third test data TD3 for the plurality of third test cases TC3.

The common test case TCc among a plurality of first test cases TC1, a plurality of second test cases TC2, and a plurality of third test cases TC3 may have the first local score LS1 generated based on the first test data TD1, the second local score LS2 generated based on the second test data TD2, and the third local score LS3 generated based on the third test data TD3. Taking FIG. 9 as an example, each of the first common test case TCc1, the second common test case TCc2, and the third common test case TCc3 included in the common test case TCc may have three local scores corresponding to application of the common test case by each of the electronic devices 20_1, 20_2, 20_3.

The test group generating module TGGM finds local optimal test cases TClo1 to TClo3 for each test group TG1 to TG3 (S150).

The test group generating module TGGM may find first to third local optimal test cases TClo1 to TClo3 having the highest local score for each of a plurality of first to third test cases TC1 to TC3 for a test group TG1 to TG3.

Taking FIG. 9 as an example, the test group generating module TGGM may find a first local optimal test case TClo1 having the highest local score among the plurality of first test cases TC1 for the first test group TG1. The first local optimal test case TClo1 may be the first common test case TCc1, or another test case of the first test group TG1. The test group generating module TGGM may find a second local optimal test case TClo2 having the highest local score among the plurality of second test cases TC2 for the second test group TG2. The second local optimal test case TClo2 may be the second common test case TCc2, or another test case of the second test group TG2. The test group generation module TGGM may find a third local optimal test case TClo3 having the highest local score among the plurality of third test cases TC3 for the third test group TG3. The third local optimal test case TClo3 may be the third common test case TCc3, or another test case of the third test group TG3. The local optimal test cases are not limited to being a common test case but may include test cases included in only a subset of the test groups TG (e.g., in a single test group TG).

The test group generating module TGGM generates a plurality of global score GS based on the local scores LS for the common test cases TCc (S160).

Taking FIG. 9 as an example, the test group generating module TGGM may calculate the first to third local scores LS1 to LS3 for the first common test case TCc1 to generate the global score GS for the first common test case TCc1, using one or more operations based on the first to third local scores LS1 to LS3 for the first common test case TCc1. The operations may include arithmetic mean, geometric mean, minimum selection, and/or weighted operations, but are not limited to. Similarly, the test group generating module TGGM may calculate the first to third local scores LS1 to LS3 for the second common test case TCc2 to generate the global score GS for the second common test case TCc2 and calculate the first to third local scores LS1 to LS3 for the third common test case TCc3 to generate the global score GS for the third common test case TCc3.

The global score GS may be a performance indicator reflecting the first to third test data TD1 to TD3 measured across the first to third electronic devices 20_1 to 20_3.

The test group generating module TGGM replaces the local score LS with the global score GS for the common test case TCc to generate a test score TS for each test group TG1 to TG3 (S170).

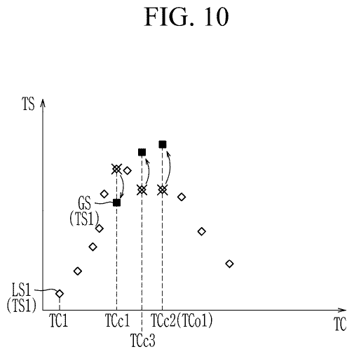

With additional reference to FIG. 10, the test group generating module TGGM may generate a plurality of first test scores TS1 for the plurality of first test cases TC1 by replacing the first local score LS1 for the first to third common test cases TCc1 to TCc3 with the global score GS, among the plurality of first local scores LS1 for the plurality of first test cases TC1. Similarly, the test group generating module TGGM may generate second test scores for the plurality of second test cases TC2 by replacing the second local scores LS2 for the first to third common test cases TCc1 to TCc3 with the global score GS among the plurality of second local scores LS2 for the plurality of second test cases TC2. The test group generating module TGGM may generate third test scores for a plurality of third test cases TC3 by replacing the third local scores LS3 for the first to third common test cases TCc1 to TCc3 with the global score GS among the plurality of third local scores LS3 for the plurality of third test cases TC3. Local scores for non-common test cases may remain, e.g., may not be replaced.

The test score TS may be a performance indicator that reflects both a local score LS obtained from a specific electronic device and a global score GS obtained from multiple electronic devices 20_1 to 20_3.

The first test score TS1 for the first to third common test cases TCc1 to TCc3 may be a global score GS, and the first test score TS1 for each first test case TC1 excluding the first to third common test cases TCc1 to TCc3 may be a first local score LS1. Similarly, the second test score for the first to third common test cases TCc1 to TCc3 may be a global score GS, and the second test score for each second test case TC2 excluding the first to third common test cases TCc1 to TCc3 may be a second local score LS2. Similarly, the third test score for the first to third common test cases TCc1 to TCc3 may be a global score GS, and the third test score for each third test case TC3 excluding the first to third common test cases TCc1 to TCc3 may be a third local score LS3. As such, for each electronic device 20_1 to 20_3, the test group generating module TGGM can obtain (i) one or more local scores LS corresponding, respectively, to one or more non-common test cases applied by the electronic device (e.g., only by the electronic device, or by only a subset of the electronic devices), and (ii) one or more global scores GS corresponding, respectively, to one or more common test cases applied by each electronic device.

The test group generating module TGGM finds the optimal test case TCo1 to TCo3 for each test group TG1 to TG3 (S180), e.g., from among the sets of scores obtained by operation S170.

The test group generating module TGGM may find the first to third optimal test cases TCo1 to TCo3 having the highest test score for each of a plurality of first to third test cases TC1 to TC3 for a test group TG1 to TG3.

Taking FIG. 10 as an example, the test group generating module TGGM may find the first optimal test case TCo1 with the highest test score among a plurality of first test cases TC1 for the first test group TG1. In this example. the first optimal test case TCo1 is the second common test case TCc2. Similarly, the test group generating module TGGM may find a second optimal test case TCo2 (not separately labeled) having the highest test score among multiple second test cases TC2 for the second test group TG2. The test group generating module TGGM may find a third optimal test case TCo3 (not separately labeled) with the highest test score among multiple third test cases TC3 for the third test group TG3.

The genetic algorithm tool GAT checks that the test is completed (S190).

The genetic algorithm tool GAT may check that the genetic algorithm operation of the test system 1 is completed based on a predetermined complete condition. The predetermined complete condition may include information about the generation that is the target of the test operation or the total number of measurement operations in the test system 1, but is not limited to those operations.

In response to the completion of the test, the genetic algorithm tool GAT selects the test case with the highest global score GS (S200).

The genetic algorithm tool GAT may select the test case with the highest global score GS among common test cases TCc, and the test case selected may include a combination of operating conditions robust across multiple electronic devices 20_1 to 20_3.

If the test is not completed, the genetic algorithm tool GAT generates subsequent test groups TGs1 to TGs3 based on the optimal test cases TCo1 to TCo3 and the local optimal test cases TClo1 to TClo3 for each test group TG1 to TG3 (S210).

The genetic algorithm tool GAT may generate subsequent test groups TGs1 to TGs3, which are subsequent generations of test groups TG1 to TG3, based on optimal test cases TCo1 to TCo3 and multiple local optimal test cases TClo1 to TClo3.

With additional reference to FIG. 11, the mutation module GAM performs mutation operations based on the optimal test cases TCo1 to TCo3 for each test group TG1 to TG3 to generate pre-test groups TGp1 to TGp3 for the test groups TG1 to TG3 (S211).

The mutation module GAM may receive optimal test cases TCo1 to TCo3 for each test group TG1 to TG3 from the test group generation module TGGM.

The mutation module GAM may perform mutation operations based on each optimal test case TCo1 to TCo3 to generate pre-test groups TGp1 to TGp3 for each test group TG1 to TG3.

The mutation module GAM may randomly modify at least some of the operating conditions within the first to third optimal test cases TCo1, TCo2, TCo3 in the mutation operation, and the operating conditions may be freely modified as long as it does not exceed the predefined range in the mutation operation. In mutation operations, information on the operation condition can be freely modified as long as it does not exceed from a predefined mutation rate.

The mutation module GAM may perform a mutation operation based on the first optimal test case TCo1 to generate the first pre-test group TGp1, perform a mutation operation based on the second optimal test case TCo2 to generate the second pre-test group TGp2, and perform a mutation operation based on the third optimal test case TCo3 to generate the third pre-test group TGp3.

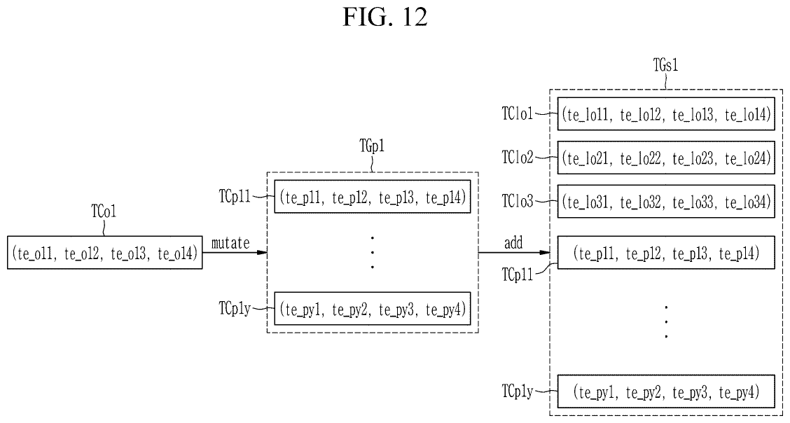

Taking FIG. 12 as an example, the mutation module GAM may randomly modify at least a part of the first optimal operating conditions te_o11 to te_o14 of the first optimal test case TCo1 to generate the 1_1 to 1_y pre-test cases TCp11 to TCp1y for the first preliminary test group TGp1. For example, the mutation module GAM may generate the 1_1 to 1_4 pre-operating conditions te_p11 to te_p14 for the 1_1 pre-test case TCp11 by modifying at least a part of the first optimal operating conditions te_o11 to te_o14. Similarly, the mutation module GAM may generate the 1_y pre-operating conditions te_py1 to te_py4 for the 1_y pre-test case TCp1y by modifying at least some of the first optimal operating conditions te_o11˜te_o14. The above y is a predetermined natural number and may, for example, be determined inversely proportional to the number of multiple electronic devices 20_1 to 20_3.

The genetic algorithm tool GAT may perform mutation operations based on an optimal test case having the highest test score for each electronic device 20_1 to 20_3, to generate first to third pre-test groups TGp1 to TGp3 reflecting all of the plurality of electronic devices 20_1 to 20_3.

The test group generation module TGGM adds local optimal test cases TClo1 to TClo3 for multiple test groups TG1 to TG3 to each of the first to third pre-test group TGp1 to TGp3 to generate subsequent test groups TGs1 to TGs3 for the test groups TG1 to TG3 (S212).

The test group generation module TGGM may receive each of the pre-test groups TGp1 to TGp3 for each of the first to third test groups TG1 to TG3 from the mutation module GAM.

The test group generating module TGGM may add multiple local optimal test cases TClo1 to TClo3 to each of the first to third pre-test groups TGp1 to TGp3 and generate multiple subsequent test cases in subsequent test groups TGs1 to TGs3.

Taking FIG. 12 as an example, the test group generating module TGGM may add multiple local optimal test cases TClo1 to TClo3 to the first pre-test group TGp1 to generate the first subsequent group TGs1 for the first test group TG1. Similarly, the test group generation module TGGM may add multiple local optimal test cases TClo1 to TClo3 to the second pre-test group TGp2 to generate the second subsequent test group TGs2 for the second test group TG2. The test group generating module TGGM may add multiple local optimal test cases TClo1 to TClo3 to the third pre-test group TGp3 to generate the third subsequent test group TGs3 for the third test group TG3.

The genetic algorithm tool GAT can cross-validate a local optimal test case for a specific electronic device to multiple electronic devices 20_1 to 20_3 by adding multiple local optimal test cases TClo1 to TClo3 to each pre-test group TGp1 to TGp3. In addition, the genetic algorithm tool GAT can ensure common test cases TCc common to multiple test groups TG1 to TG3 by adding multiple local optimal test cases TClo1 to TClo3 to each pre-test group TGp1 to TGp3.

If the test is not completed, the genetic algorithm tool GAT may perform the genetic algorithm operation by repeatedly performing step S200 and steps S120 to S180.

The genetic algorithm tool GAT can efficiently search a search space SS in a direction robust across multiple electronic devices 20_1 to 20_3 by repeatedly performing steps S200 and S120 to S180.

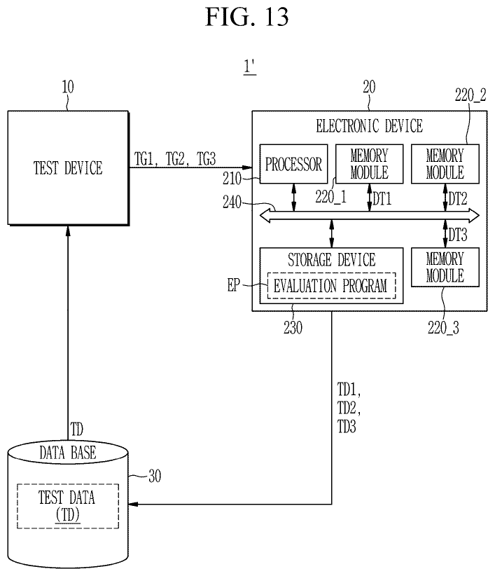

FIG. 13 is a block diagram illustrating an example of a test system. Each of the test device 10, the electronic device 20′, and the database 30 of FIG. 13 may correspond to (e.g., be substantially similar to) each of the test device 10, the plurality of electronic devices 20, and the database 30 of FIG. 1, respectively. For ease of explanation below, the test device 10, the electronic device 20′, and the database 30 of FIG. 13 will be described with a focus on differences from the test device 10, the plurality of electronic devices 20, and the database 30 of FIG. 1.

Referring to FIG. 13, the test system 1′may include the test device 10, the electronic device 20′, and the database 30.

The test device 10 may be controlled to provide the first to third test groups TG1 to TG3 to one electronic device 20′.

The electronic device 20′may include a device processor 210, first to third memory modules 220_1 to 220_3, a device storage device 230, and a system bus 240. The electronic device 20′ may be a computer-based test device that is also the environment of the DUT. Each of the device processor 210, the first to third memory modules 220_1 to 220_3, the device storage devices 230, and the system bus 240 may correspond to the first to third processors 210_1 to 210_3, the first to third memory modules 220_1 to 220_3, the first to third storage devices 230_1 to 230_3, and the first to third system buses 240_1 to 240_3 of FIG. 1, respectively.

For ease of explanation below, the device processor 210, the first to third memory modules 220_1 to 220_3, the device storage device 230, and the system bus 240 will be described below, focusing on differences between the first to third processors 210_1 to 210_3, the first to third memory modules 220_1 to 220_3, the first to third storage devices 230_1 to 230_3, and the first to third system buses 240_1 to 240_3.

The device processor 210 may execute a measurement program EP to apply a test case of the first test group TG1 to the first memory module 220_1, perform a measurement operation according to the application of the test case, and perform various processing operations related to the measurement operation. In addition, the device processor 210 may execute a measurement program EP to apply a test case of the second test group TG2 to the second memory module 220_2, perform a measurement operation according to the application of the test case, and perform various processing operations related to the measurement operation. The device processor 210 may execute a measurement program EP to apply a test case of the third test group TG3 to the third memory module 220_3, perform a measurement operation according to the application of the test case, and perform various processing operations related to the measurement operation.

For example, the device processor 210 may execute a measurement program EP to apply a test case of the first test group TG1 to the first memory module 220_1 and control the input/output operation of a first data signal DT1 input/output from the first memory module 220_1. The device processor 210 may execute the measurement program EP to measure a signal margin for the first data signal DT1 and generate first test data TD1. Similarly, the device processor 210 may execute the measurement program EP to apply a test case of the second test group TG2 to the second memory module 220_2 and control the input/output operation of a second data signal DT2 input/output from the second memory module 220_2. The device processor 210 may execute the measurement program EP to measure a signal margin for the second data signal DT2 and generate second test data TD2. Similarly, the device processor 210 may execute the measurement program EP to apply a test case of the third test group TG3 to the third memory module 220_3 and control the input/output operation of a third data signal DT3 input/output from the third memory module 220_3. The device processor 210 may execute the measurement program EP to measure a signal margin for a third data signal DT3 and generate third test data TD3.

Each of the first to third memory modules 220_1 to 220_3 may be an individual DUT. Each of the first to third memory modules 220_1 to 220_3 may be used as a main memory or system memory of the electronic device 20′. The measurement program EP running on the device processor 210 may be loaded into the first to third memory modules 220_1 to 220_3.

The first memory module 220_1 input and output the first data signal DT1 along with the execution of the measurement program EP. The device processor 210 may perform a measurement operation according to the application of a test case within the first test group TG1 and generate first test data TD1 by executing the measurement program EP loaded into the first memory module 220_1. The second memory module 220_2 may input and output the second data signal DT2 along with the execution of the measurement program EP. The device processor 210 may perform a measurement operation according to the application of a test case within the second test group TG2 and generate second test data TD2 by executing the measurement program EP loaded into the second memory module 220_2. The third memory module 220_3 may input and output the third data signal DT3 along with the execution of a measurement program EP. The device processor 210 may perform a measurement operation according to the application of a test case within the third test group TG3 and generate third test data TD3 by executing a measurement program EP loaded into the third memory module 220_3.

The first to third test data TD1 to TD3 generated in the electronic device 20′ may be transmitted to the database 30 and stored in the database 30.

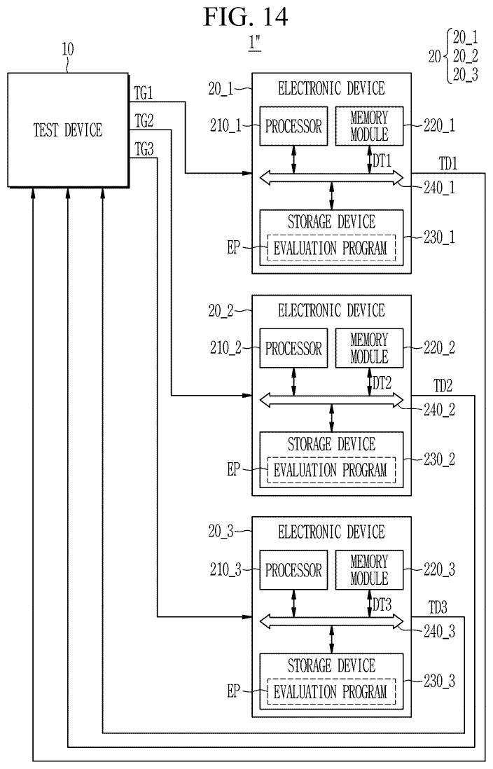

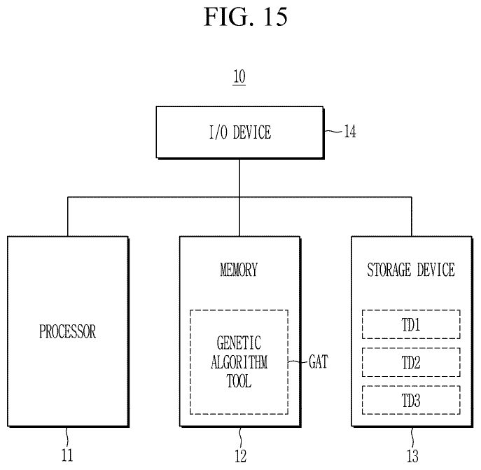

FIG. 14 is a block diagram illustrating an example of a test system. FIG. 15 is a block diagram illustrating an example of a test device. Each of the test device 10 and the plurality of electronic devices 20 of FIGS. 14 and 15 may correspond to (e.g., be substantially similar to) each of the test device 10 and the plurality of electronic devices 20 of FIG. 1, respectively. For ease of explanation below, the test device 10 and the plurality of electronic devices 20 of FIGS. 14 and 15 will be described with a focus on differences from the test device 10 and the plurality of electronic devices 20 of FIG. 1.

A test system 1″ may include the test device 10 and the plurality of electronic devices 20.

The test device 10 may include a processor 11, a memory 12, a storage device 13, and an input/output device 14. Each of the processor 11, the memory 12, the storage device 13, and input/output device 14 of FIG. 15 may correspond to each of the processor 11, memory 12, storage device 13, and input/output device 14 of FIG. 2, respectively. For ease of explanation below, the processor 11, the memory 12, the storage device 13, and the input/output device 14 of FIG. 15 will be described with a focus on differences from the processor 11, the memory 12, the storage device 13, and input/output device 14 of FIG. 2.

The storage device 13 may store program codes (e.g., computer-readable program codes) for executing the genetic algorithm tool GAT and the first to third test data TD1 to TD3 generated from the first to third electronic devices 20_1 to 20_3.

The first to third test data TD1 to TD3 generated from first to third electronic devices 20_1 to 20_3 may be transmitted to a test device 10 and stored in a storage device 13 of the test device 10.

While this disclosure contains many specific implementation details, these should not be construed as limitations on the scope of what may be claimed. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

Although examples have been described in detail above, the scope of the present disclosure is not limited thereto, and various modifications and improvements made by those skilled in the art also fall within the scope of the present disclosure.

What is claimed is:

1. A testing method for an electronic device, the testing method comprising:
receiving a plurality of first test data for a plurality of first test cases and a plurality of second test data for a plurality of second test cases, wherein the plurality of first test data and the plurality of second test data indicate results of one or more electronic devices applying the plurality of first test cases and the plurality of second test cases to perform operations;
generating a plurality of first local scores based on the plurality of first test data;
generating a plurality of second local scores based on the plurality of second test data;
generating a global score based on common test data of the plurality of first test data and the plurality of second test data, wherein the common test data corresponds to a common test case that is included in the plurality of first test cases and in the plurality of second test cases;
replacing a first local score of the plurality of first local scores with the global score to generate a plurality of first test scores;
replacing a second local score of the plurality of second local scores with the global score to generate a plurality of second test scores; and
performing a first mutation operation based on a first optimal test case corresponding to a highest score among the plurality of first test scores, to generate test cases of a first pre-test group,
wherein the test cases of the first pre-test group are configured to be provided to at least one electronic device of the one or more electronic devices, to cause the at least one electronic device to apply the test cases of the first pre-test group to perform the operations.

2. The testing method of claim 1, wherein:
the plurality of first test data are measured in a first electronic device based on operation of the first electronic device using a plurality of operating conditions of the plurality of first test cases, and
the plurality of second test data are measured in a second electronic device, different from the first electronic device, based on operation of the second electronic device using a plurality of operating conditions of the plurality of second test cases.

3. The testing method of claim 2, wherein:
the plurality of first test data includes first signal characteristics of a plurality of first data signals output from a first memory module in the first electronic device based on the operation of the first electronic device using the plurality of operating conditions of the plurality of first test cases, and
the plurality of second test data includes second signal characteristics of a plurality of second data signals output from a second memory module in the second electronic device based on the operation of the second electronic device using the plurality of operating conditions of the plurality of second test cases.

4. The testing method of claim 3, wherein generating the plurality of first local scores comprises generating the plurality of first local scores based on first timing margins and first voltage margins of the first signal characteristics.

5. The testing method of claim 3, wherein the plurality of operating conditions of the plurality of first test cases comprise mode register set (MRS) information for the first memory module.

6. The testing method of claim 1, wherein:
the plurality of first test data are measured in a first memory module in a first electronic device based on operation of the first memory module using a plurality of operating conditions of the plurality of first test cases, and
the plurality of second test data are measured in a second memory module, different from the first memory module, in the first electronic device based on operation of the second memory module using a plurality of operating conditions of the plurality of second test cases.

7. The testing method of claim 1, comprising:
performing a second mutation operation based on a second optimal test case corresponding to a highest score among the plurality of second test scores, to generate test cases of a second pre-test group,
wherein the test cases of the second pre-test group are configured to be provided to at least one electronic device of the one or more electronic devices, to cause the at least one electronic device receiving the test cases of the second pre-test group to apply the test cases of the second pre-test group to perform the operations.

8. The testing method of claim 1, wherein generating the global score comprises generating the global score based on:
a third local score of the plurality of first local scores, wherein the third local score corresponds to the common test case, and
a fourth local score of the plurality of second local scores, wherein the fourth local score corresponds to the common test case.

9. The testing method of claim 8, wherein generating the global score comprises determining an arithmetic mean of the third local score and the fourth local score.

10. The testing method of claim 1, further comprising:
adding a first local optimal test case corresponding to a highest score among the plurality of first local scores and a second local optimal test case corresponding to a highest score among the plurality of second local scores to the first pre-test group to generate a plurality of third test cases.

11. The testing method of claim 1, wherein the plurality of first test cases comprise at least one of: a core voltage of a row decoder or a column decoder of the at least one electronic device, an input/output voltage in a data input/output buffer of the at least one electronic device, a reference voltage in the at least one electronic device, or time information in the data input/output buffer.

12. A testing method for an electronic device, the testing method comprising:
receiving a plurality of first test data for a plurality of first test cases and a plurality of second test data for a plurality of second test cases, wherein the plurality of first test data and the plurality of second test data indicate results of one or more electronic devices applying the plurality of first test cases and the plurality of second test cases to perform operations;
generating a plurality of first local scores based on the plurality of first test data;
generating a plurality of second local scores based on the plurality of second test data;
performing a first mutation operation based on at least one of the plurality of first test cases to generate test cases of a first pre-test group;
performing a second mutation operation based on at least one of the plurality of first test cases to generate test cases of a second pre-test group; and
adding a first local optimal test case corresponding to a highest score among the plurality of first local scores and a second local optimal test case corresponding to the highest score among the plurality of second local scores to the first pre-test group to generate a subsequent test group that includes the test cases of the first pre-test group, the first local optimal test case, and the second local optimal test case,
wherein the subsequent test group is configured to be provided to at least one electronic device of the one or more electronic devices, to cause the at least one electronic device to apply the subsequent test group to perform the operations.

13. The testing method of claim 12, comprising:
generating a global score based on common test data of the plurality of first test data and the plurality of second test data, wherein the common test data corresponds to a common test case that is included in the plurality of first test cases and in the plurality of second test cases;
replacing at least one of the plurality of first local scores with the global score to generate a plurality of first test scores; and
replacing at least one of the plurality of second local scores with the global score to generate a plurality of second test scores, wherein:
generating the test cases of the first pre-test group includes performing the first mutation operation based on a first optimal test case corresponding to a highest score among the plurality of first test scores,
generating the test cases of the second pre-test group includes performing the second mutation operation based on a second optimal test case corresponding to a highest score among the plurality of second test scores.

14. The testing method of claim 13, wherein generating the global score comprises generating the global score based on:
a third local score of the plurality of first local scores, wherein the third local score corresponds to the common test case, and
a fourth local score of the plurality of second local scores, wherein the fourth local score corresponds to the common test case.

15. The testing method of claim 12, wherein the plurality of first test cases comprise at least one of: a core voltage of a row decoder or a column decoder of the at least one electronic device, an input/output voltage in a data input/output buffer of the at least one electronic device, a reference voltage in the at least one electronic device, or time information in the data input/output buffer.

16. The testing method of claim 12, wherein:
the plurality of first test data are measured in a first electronic device based on operation of the first electronic device using a plurality of operating conditions of the plurality of first test cases, and
the plurality of second test data are measured in a second electronic device, different from the first electronic device, based on operation of the second electronic device using a plurality of operating conditions of the plurality of second test cases.

17. A test system comprising:
a first electronic device comprising a first memory module configured to output a plurality of first data by operating using operation conditions of a plurality of first test cases, wherein the first electronic device is configured to generate a plurality of first test data based on the plurality of first data;
a second electronic device comprising a second memory module configured to output a plurality of second data by operating using operation conditions of a plurality of second test cases, wherein the second electronic device is configured to generate a plurality of second test data based on the plurality of second data; and
a test device configured to:
generate a plurality of first local scores based on the plurality of first test data,
generate a plurality of second local scores based on the plurality of second test data,
generating a global score based on common test data of the plurality of first test data and the plurality of second test data, wherein the common test data corresponds to a common test case that is included in the plurality of first test cases and in the plurality of second test cases,
replace at least one of the plurality of first local scores with the global score to generate a plurality of first test scores,
replace at least one of the plurality of second local scores with the global score to generate a plurality of second test scores, and
perform a first mutation operation based on a first optimal test case corresponding to the highest score among the plurality of first test scores to generate test cases of a first pre-test group,
wherein the test cases of the first pre-test group are configured to be provided to the first electronic device, to cause the first memory module operate using the test cases of the first pre-test group,

18. The test system of claim 17, wherein:
the test device is configured to add a first local optimal case corresponding to a highest score among the plurality of first local scores and a second local optimal case corresponding to a highest score among the plurality of second local scores to the first pre-test group to generate a plurality of third test cases.

19. The test system of claim 17, further comprising:
a database configured to store the plurality of first test data and the plurality of second test data,
wherein the test device is configured to receive the plurality of first test data and the plurality of second test data from the database.

20. The test system of claim 18, wherein the test device includes a storage device configured to store the plurality of first test data and the plurality of second test data.
